(19) United States
(12) Patent Application Publication
(10) Pub. No.: US 2007/0230646 A1
(43) Pub. Date: Oct. 4, 2007

(54) PHASE RECOVERY FROM FORWARD CLOCK

(76) Inventors: Gerald R. Talbot, Concord, MA (US); Emerson Fang, Fremont, CA (US)

Correspondence Address: ZAGORIN O'BRIEN GRAHAM LLP, 7600B NORTH CAPITAL OF TEXAS HIGHWAY, SUITE 350, AUSTIN, TX, 78731, US

(21) Appl. No.: 11/627,578

(22) Filed: Jan. 26, 2007

Related U.S. Application Data
(60) Provisional application No. 60/786,546, filed on Mar. 28, 2006.
(60) Provisional application No. 60/745,479, filed on Apr. 24, 2006.

(51) Int. Cl. H04L 7/00; H03D 3/24

(52) U.S. Cl. 375/355; 375/375

(57) ABSTRACT

A clock phase recovery circuit in a communications receiver generates a sample clock signal for recovering data from a received data signal. The sample clock signal is based at least in part on phase difference information associated with the received clock signal and the received data signal. The received clock signal and received data signal are separately received by a receive interface circuit from a transmit interface circuit over a data communications link. Transmit clock jitter is effectively a common mode phase variation that is substantially rejected by the clock phase recovery circuit. Accordingly, the transmit clock jitter can be greater than otherwise allowable.

### CROSS-REFERENCE TO RELATED APPLICATION(S)

This application claims benefit under 35 U.S.C. § 119 of provisional application No. 60/786,546, filed Mar. 28, 2006, entitled “Method and Apparatus for Link Operations,” naming Gerry R. Talbot, Paul Miranda, Mark D. Hummel, William A. Hughes, and Larry D. Hewitt as inventors, which application is incorporated by reference herein. This application also claims benefit under 35 U.S.C. § 119 of provisional application No. 60/745,479, filed Apr. 24, 2006, entitled “Phase Recovery From Forward Clock,” naming Gerald R. Talbot and Emerson Fang as inventors, which application is incorporated by reference herein.

### BACKGROUND

1. Field of the Invention

This application is related to integrated circuits and more particularly to data communications links between integrated circuits.

2. Description of the Related Art

To properly recover data received by an integrated circuit node transmitted across a data communications link by another integrated circuit node, the receiving node must sample the data during an appropriate phase of the data signal. A transmitting node compliant with an exemplary communications link may transmit, on a separate signal line, a reference clock for use in sampling commands, addresses or data (hereinafter, “data”) by the receiving node. However, introduction of skew between received data and a received sample clock (e.g., skew introduced by the channel of the communications link, the receiver, or other sources) may compromise data recovery. For example, if skew between the reference clock and the received data causes data transitions to approach the sampling point, the data transitions may fall within the clock setup time of a sampling device (e.g., flip flop or other state element) causing errors in data recovery. In addition, the phase relationship between the received clock signal and the received data signal may not be stationary, which adds complexity to clock and data recovery operations. Accordingly, techniques for maintaining the integrity of data recovered by a receiving node on a data communications link are desired.

### SUMMARY

A clock phase recovery circuit in a communications receiver generates a sample clock signal for recovering data from a received data signal. The sample clock signal is based at least in part on phase difference information associated with the received clock signal and the received data signal. The received clock signal and received data signal are separately received by a receive interface circuit from a transmit interface circuit over a data communications link. Transmit clock jitter is effectively a common mode phase variation that is substantially rejected by the clock phase recovery circuit. Accordingly, the transmit clock jitter can be greater than otherwise allowable.

In at least one embodiment of the invention, an apparatus includes a circuit on a first integrated circuit coupled to receive, from a second integrated circuit, at least one received data signal and a received clock signal on separate communications paths. The circuit is coupled to generate a sample clock signal and a sampled data signal. The sampled data signal is the received data signal sampled by the sample clock signal. The sample clock signal is determined at least in part according to a phase difference between the received clock signal and the received data signal.

In at least one embodiment of the invention, a method includes generating a sample clock signal on a first integrated circuit based at least in part on a phase difference between a received clock signal received from a second integrated circuit and a received data signal. The received data signal is received from the second integrated circuit separately from the received clock signal.

### BRIEF DESCRIPTION OF THE DRAWINGS

The present invention may be better understood, and its numerous objects, features, and advantages made apparent to those skilled in the art by referencing the accompanying drawings.

FIG. 1 illustrates a block diagram of two integrated circuit devices coupled by a communications link consistent with one or more embodiments of the present invention.

FIG. 2 illustrates a block diagram of a portion of a communications link receive path on an integrated circuit device consistent with one or more embodiments of the present invention.

FIG. 3 illustrates a block diagram of an exemplary clock phase recovery circuit consistent with one or more embodiments of the present invention.

FIG. 4 illustrates a block diagram of an exemplary portion of the clock phase recovery circuit of FIG. 3 consistent with one or more embodiments of the present invention.

FIG. 5 illustrates a block diagram of an exemplary phase shifting circuit of a clock phase recovery circuit of FIG. 3 consistent with one or more embodiments of the present invention.

The use of the same reference symbols in different drawings indicates similar or identical items.

### DESCRIPTION OF THE PREFERRED EMBODIMENT(S)

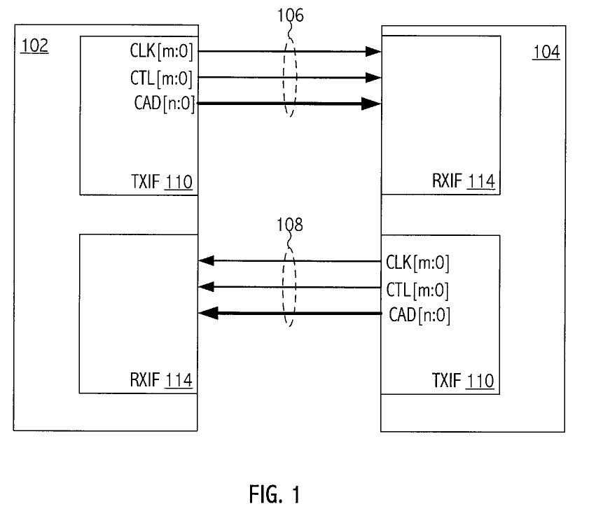

Referring to FIG. 1, integrated circuit 102 communicates with integrated circuit 104 by an exemplary communications link including transmit interfaces 110, receive interfaces 114, and communications paths 106 and 108, which include respective, individual communications paths for clock signals (e.g., CLK[m:0]), control signals (e.g., CTL[m:0]), and data signals (e.g., n-bits of commands, addresses, or data, i.e., CAD[n:0]). Those individual communications paths may be single-ended or differential communications paths. In at least one embodiment of the invention, a bit-time is half a clock period in duration, i.e., two data bits (e.g., two CAD[n:0] bits or two CTL[m:0] bits) are transmitted on a corresponding communications path per clock cycle (e.g., a period of a respective one of CLK[m:0]). However, the teachings herein may be adapted for bit-times having one clock period in duration (i.e., one data bit is transmitted on a corresponding communications path per clock cycle) or for other suitable bit-time durations. Communications paths 106 and 108 are unidirectional, i.e., communications path 106 provides a path from integrated circuit 102 to integrated circuit 104 and communications path 108 provides a path to integrated circuit 102 from integrated circuit 104.

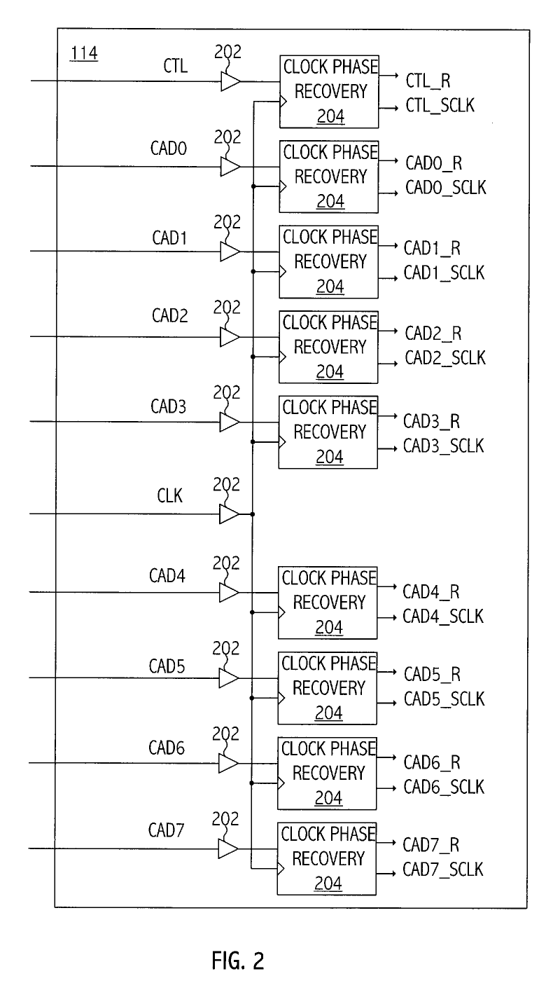

Referring to FIG. 2, the exemplary, individual communications paths, CLK, CTL, and CAD[7:0] in integrated circuit 104 are received by individual receivers 202 and individual clock phase recovery circuits 204 in receive interface 114. Receivers 202 may perform signal equalization, signal level shifting, noise reduction, or other appropriate signal processing functions. Exemplary clock phase recovery circuits 204 individually receive a received clock signal (i.e., a forward clock signal, e.g., CLK) in addition to a respective, received data signal (e.g., CTL, CAD0, CAD1, . . . , CAD7). Clock phase recovery circuits 204 generate corresponding sample clocks (e.g., CTL_SCLK, CAD0_SCLK, CAD1_SCLK, . . . , CAD7_SCLK) and provide the recovered data (e.g., CTL_R, CAD1_R, CAD2_R, . . . CAD7_R) to other circuitry of receive interface 114. An individual sample clock signal (e.g., CAD4_SCLK) is a dynamically delayed version of the received clock signal (e.g., CLK), which is dynamically delayed based at least in part on a phase difference between the received clock signal and the corresponding received data signal (e.g., CAD4).

In at least one embodiment, individual ones of clock phase recovery circuits 204 generate a sample clock signal for sampling the received data signal at the center of a data eye of the received data signal. The phase difference between the received clock signal and the received data signal may be nonstationary, i.e., this phase difference varies during a period of communications link operation. Thus, the delay applied to the received clock signal to generate the sample clock signal is adjusted during the period of communications link operation, accordingly. In at least one embodiment of clock phase recovery circuits 204, the phase difference between the received clock signal and the received data signal at the receiver is less than a particular transport phase difference threshold value (e.g., 3 unit intervals or bit-times). However, the phase difference between the sample clock signal and the received data signal may be greater than that particular transport phase difference threshold value.

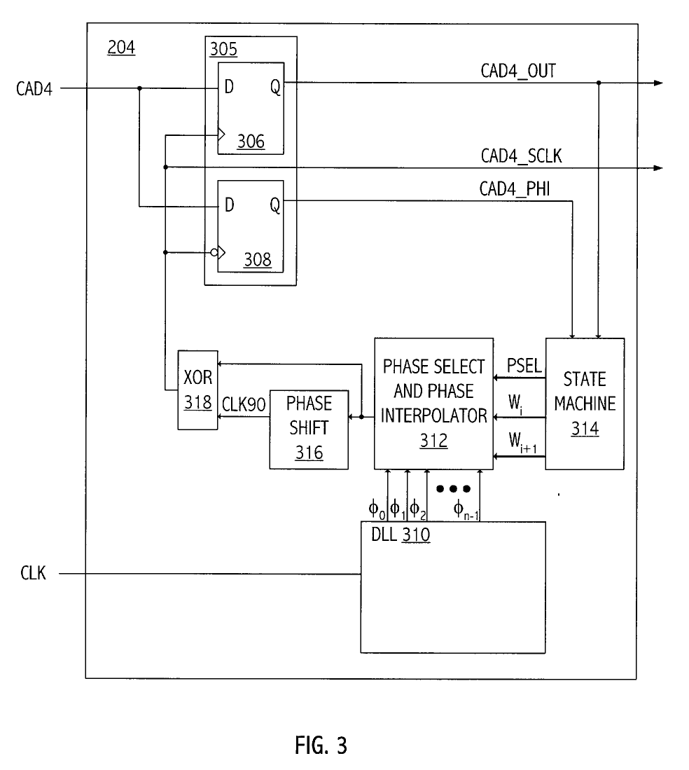

An exemplary clock phase recovery circuit (e.g., clock phase recovery circuit 204), consistent with at least one embodiment of the invention, is illustrated in FIG. 3. Clock phase recovery circuit 204 recovers phase information from the received data signal (e.g., CAD4) and the received clock signal (e.g., CLK) to generate a sample clock signal (e.g., CAD4_SCLK) and a sampled data signal (CAD4_OUT). Phase detector 305 includes two flip-flops (e.g., flip-flop 306 and flip-flop 308) that sample the received data signal based on the sample clock signal (e.g., CAD4_SCLK) 180° out of phase with each other. Phase detector 305 provides two signals, a sampled received data signal and a signal providing phase information, e.g., CAD4_OUT and CAD4_PHI, respectively. Those signals are indicative of the phase difference between the received data signal and the received clock signal and are provided to state machine 314.

State machine circuit 314 generates digital control signals (e.g., PSEL, Wᵢ, and Wᵢ₊₁) for adjusting the sample clock signal based on a comparison of CAD4_OUT to CAD4_PHI. State machine circuit 314 controls a phase selection and phase interpolation circuit, (e.g., phase select and phase interpolator circuit 312) to generate the sample clock signal based at least in part on the received clock signal to generate the sample clock signal having a target phase relationship to the received data signal. For example, state machine 314 may generate control signals PSEL, Wᵢ, and Wᵢ₊₁ to apply an appropriate delay to the received clock signal to generate the sample clock signal to sample the received data signal in substantially the center of the data eye. State machine 314 determines whether the phase of the sample clock signal is early or late with respect to the received data signal and issues a phase change request (e.g., appropriate values of PSEL, Wᵢ, and Wᵢ₊₁) based on this determination. The phase change request applies a delay to shift the phase of the sample clock signal in a direction that aligns the sample clock signal with an appropriate phase of the data. Note that the relationship between phase (φ, in degrees) and delay (t_{D}, in seconds) is φ=360*t_{D}*f (where frequency, f, is measured in Hz). In at least one embodiment of state machine 314, digital circuitry included in state machine 314 is responsive to a clock derived from the sample clock signal. However, other clock signals of suitable frequency may be used by state machine 314.

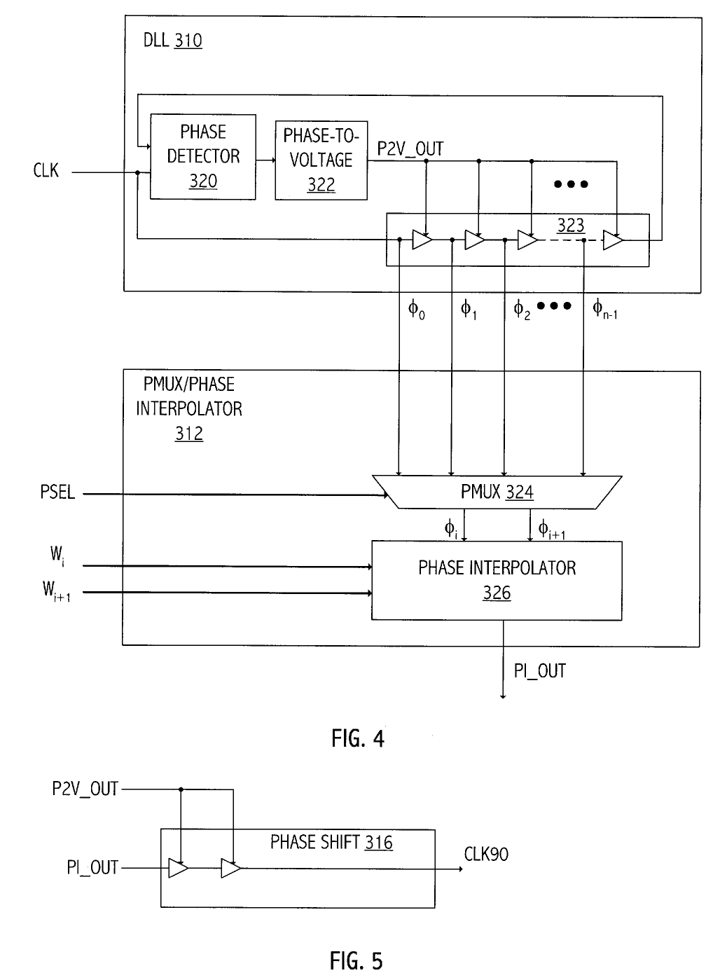

In addition to receiving control signals from state machine circuit 314, phase select and phase interpolation circuit 312 receives n phase signals from delay-locked loop (DLL) 310 (e.g., φ₀, φ₁, . . . , φₙ₋₁), which generates these signals based on the received clock signal. Referring to FIG. 4, in at least one embodiment of clock phase recovery circuit 204, DLL 310 includes a delay line (e.g., delay line 323) that is configured to have a total delay equal to the period of the received clock signal. Phase signals φ₀, φ₁, . . . , φₙ₋₁ are spaced evenly to cover the 360° phase space of the received clock signal. Phase signals φ₀, φ₁, . . . , φₙ₋₁ may include n/2 true phase signals (e.g., φ₀, φ₁, . . . , φ_{n/2-1}) and corresponding n/2 complementary phase signals (e.g., φ_{0B}, φ_{1B}, . . . , φ_{(n/2-1)B}) in implementations of clock phase recovery circuit 204 that include complementary delay lines in DLL 310, as discussed below.

Delay-locked loop 310 includes a feedback loop including phase detector 320, which may be any suitable phase detector that compares the received clock signal to a delayed version of the received clock signal to generate a phase difference signal. That phase difference is applied to delay line 323. For example, delay line 323 may be a voltage-controlled delay line. The phase difference may be converted by phase-to-voltage circuit 322 into a voltage (e.g., P2V_OUT) that is applied to delay line 323 to adjust the delay of individual delay elements of the delay line to be equivalent and to have a duration that provides a cumulative delay of the delay line equal to the period of the received clock. In at least one embodiment of the invention, the delay line is a current-controlled delay line and the phase difference is converted by an appropriate circuit, accordingly. Phase signals φ₀, φ₁, . . . , φₙ₋₁ are versions of the received clock delayed by equivalent increments from next adjacent phase signals. Those phase signals may be generated by tapping off nodes of the delay line. In an exemplary DLL 310, DLL 310 locks at the 180° point of the received clock signal, which is a half-rate clock signal (e.g., 2.6 GHz at a 5.2 Gbps data rate) to provide a total delay that is equal to one unit interval or bit-time (e.g., 192 ps for a 2.6 GHz received clock signal).

In an exemplary embodiment of clock phase recovery circuit 204, DLL 310 is a delay line that includes two complementary delay lines driven by complementary versions of the received clock signal. The two complementary delay lines are tapped after each inverter of the delay lines to provide phase-adjacent signals separated by only one inverter delay, thereby improving phase resolution by a factor of two of the individual delay lines. In such an exemplary DLL 310, DLL 310 locks at the 180° point of the received clock signal, which is a half-rate clock signal (e.g., 2.6 GHz at a 5.2 Gbps data rate) to provide a delay of the individual ones of the complementary delay lines that is equal to one unit interval or bit-time (e.g., 192.3 ps for a 2.6 GHz received clock signal). Delay-locked loop 310 outputs true taps from delay line 323 (e.g., φ₀, φ₁, . . . , φ₅), which provide the first 180° of phase signals. In addition, DLL 310 outputs complement taps (e.g., φ_{0B}, φ_{1B}, . . . , φ_{5B}), which provide the second 180° of phase signals. The 12 phase signals cover the 360° of phase with 30° of separation between adjacent phases, each phase signal providing a delay of (30°/360°)*(1/2.6 GHz)=32.05 ps.

Since DLL 310 outputs only discrete values and the phase difference between the received clock signal and the received data signal may not be exactly one of these discrete values, phase select and phase interpolator circuit 312 selects (e.g., according to PSEL) two adjacent phase signals that have phases with respect to the received clock signal that are nearest to the phase difference to be applied to the received clock signal for use in generating the sample clock signal. Those two adjacent phase signals (e.g., φᵢ and φᵢ₊₁) are received by phase interpolator circuit 326 and a phase interpolation of the two adjacent phase signals may be performed to generate an interpolated clock signal (e.g., PI_OUT) that is used to generate the sample clock signal. Phase interpolator circuit 326 may be any suitable phase interpolation circuit. Phase interpolator designs are well known in the art and are typically dependent upon the particular DLL implementation and electrical parameters of the interface in which they operate.

The phase difference between the received clock signal and the received data signal may not fall exactly between the selected adjacent phase signals and phase interpolator 326 may not apply an equal weight to each of the adjacent phase signals. Rather, phase interpolator 326 may receive control signals (e.g., weighting signals Wᵢ and Wᵢ₊₁) generated by state machine 314 that indicate an appropriate weighting function for application to phase signals φᵢ and φᵢ₊₁ to generate the signal having an intermediate phase, e.g., PI_OUT. Accordingly, PI_OUT is an interpolated version of φᵢ and φᵢ₊₁ having a particular phase relationship with the received data signal and is used to generate the sample clock signal, which may be phase aligned with the center of the data eye of the received data signal.

In at least one embodiment of phase interpolator circuit 326, weighting signals Wᵢ and Wᵢ₊₁ are four bits wide, i.e., each of the phase signals φᵢ and φᵢ₊₁ may be weighted by sixteen different values. For example, DLL 310 provides only the exemplary discrete values 0°, 30°, 60°, 90°, 120°, . . . , 330° phase shift signals. To obtain a phase shift of 10°, which is between the discrete phase shifts of 0° and 30°, state machine 314 provides a value for Wᵢ that weights φᵢ at ⅔ and a value for Wᵢ₊₁ that weights φᵢ₊₁ at ⅓ (e.g., 0°*⅔+30°*⅓=10°).

Referring back to FIG. 3, the sample clock may be generated by an exclusive-or (e.g., as applied by XOR 318) of the intermediate phase signal (e.g., PI_OUT) with a phase-shifted version of the intermediate phase signal. For example, the intermediate phase signal is a phase-shifted version of the received clock signal and, thus, is a half-rate clock signal (e.g., 2.6 GHz at a 5.2 Gbps data rate). A full-rate clock signal (e.g., 5.2 GHz at a 5.2 Gbps data rate) is generated by exclusive-oring the intermediate phase signal with a version of the intermediate phase signal that is phase shifted by 90°. Referring to FIG. 5, an appropriate phase shift (e.g., a 90° phase shift) is generated by including within exemplary phase shift circuit 316, an appropriate fraction of the number of delay elements in the delay line 323 of DLL 310. The delay elements in phase shift circuit 316 are adjusted by the voltage generated by phase-to-voltage circuit 322 (e.g., P2V_OUT) that is applied to delay line 323 to adjust the delay of individual delay elements of delay line 323 to be equivalent and to have a duration that provides a total delay of the delay line equal to an appropriate period of the received clock signal. In at least one embodiment of the invention, P2V_OUT is applied to phase shift circuit 316 to provide a 90° phase shift. The signal generated by XOR 318 is the sample clock signal that is used to sample the received data signal. One edge of the sample clock signal (i.e., rising or falling edge) is aligned with transitions in the received data signal. The other edge of the sample clock signal is half a unit interval away from the data edge, which is generally in the center of the data eye and is used to sample the received data signal. Note that since transmit clock jitter is present in both the received data signal and the received clock signal, the transmit clock jitter is effectively a common mode phase variation that is rejected by clock phase recovery circuit 204. Accordingly, the transmit clock jitter can be greater than otherwise allowable (e.g., as compared to clock recovery techniques that do not use a forward clock).

In at least one embodiment of the invention, in a low-power mode, neither clock nor data are transmitted by transmit interface 110 on CLK or a corresponding data line. However, since phase and control information in clock phase recovery circuit 204 may be stored in a digital state, clock phase recovery circuit 204 may recover from the low-power mode by maintaining or restoring the digital state from a previously known digital state. Upon resumption of data transmission, the clock phase recovery will be faster than if DLL 310 achieves lock from an initialization state. In another low-power mode, transmit interface 110 may send a clock signal on CLK, but not send data on an individual one of CTL or CAD[n:0]. Delay-locked loop 310 may continue to operate and adjust the delay of the delay line 323. Upon resumption of data transmission, the clock phase recovery will be faster than if DLL 310 achieves lock from a previous state or from an initialization state.

While circuits and physical structures are generally presumed, it is well recognized that in modern semiconductor design and fabrication, physical structures and circuits may be embodied in computer-readable descriptive form suitable for use in subsequent design, test or fabrication stages. Structures and functionality presented as discrete components in the exemplary configurations may be implemented as a combined structure or component. The invention is contemplated to include circuits, systems of circuits, related methods, and computer-readable medium encodings of such circuits, systems, and methods, all as described herein, and as defined in the appended claims. As used herein, a computer-readable medium includes at least disk, tape, or other magnetic, optical, semiconductor (e.g., flash memory cards, ROM), or electronic medium.

The description of the invention set forth herein is illustrative, and is not intended to limit the scope of the invention as set forth in the following claims. For example, while the invention has been described in an embodiment in which the received data signals have bit-times of half the received clock period in duration, one of skill in the art will appreciate that the teachings herein can be utilized with received data signals having other bit-times. Variations and modifications of the embodiments disclosed herein, may be made based on the description set forth herein, without departing from the scope and spirit of the invention as set forth in the following claims.

What is claimed is:

1. An apparatus comprising:
a circuit on a first integrated circuit coupled to receive, from a second integrated circuit, a received clock signal and at least one received data signal on separate communications paths, the circuit being coupled to generate a sample clock signal and a sampled data signal, the sampled data signal being the received data signal sampled by the sample clock signal,
wherein the sample clock signal is determined at least in part according to a phase difference between the received clock signal and the received data signal.

2. The apparatus, as recited in claim 1, wherein the sample clock signal is determined at least in part according to a target sampling point of the received data signal.

3. The apparatus, as recited in claim 1, wherein the circuit comprises:
a delay-locked loop circuit responsive to the received clock signal to provide a plurality of phase clock signals having respective phases spaced equally across at least a predetermined fraction of the period of the received clock signal.

4. The apparatus, as recited in claim 3, wherein the circuit further comprises:
a select circuit responsive to at least one phase select signal to select from the plurality of phase clock signals, a first phase clock signal having a first phase and a second phase clock signal having a second phase different from the first phase; and
a phase interpolator circuit responsive to at least one interpolation control signal to generate an interpolated clock signal based on the first phase clock signal and the second phase clock signal.

5. The apparatus, as recited in claim 4, wherein the first and second phase clock signals are the phase clock signals of the plurality of phase clock signals nearest a target delay based at least in part on the phase difference between the received clock signal and the received data signal.

6. The apparatus, as recited in claim 4, wherein the circuit further comprises:
a control circuit responsive to at least an indicator of a phase difference between the received clock signal and the received data signal to generate the at least one phase select signal and the at least one interpolation control signal.

7. The apparatus, as recited in claim 4, wherein the circuit further comprises:
a sample clock generation circuit to generate the sample clock signal based on the interpolated clock signal and a version of the interpolated clock signal phase-shifted by a predetermined fraction of the period of the received clock signal.

8. The apparatus, as recited in claim 1, wherein the circuit comprises:
a phase detector circuit responsive to the received data signal and the sample clock signal to generate an indicator of a phase difference between the received clock signal and the received data signal.

9. The apparatus, as recited in claim 1, further comprising:
a printed circuit board including the first integrated circuit and the second integrated circuit; and
a communications link coupling the first integrated circuit to the second integrated circuit,
wherein the communications link includes a plurality of unidirectional sets of signals, at least one of the plurality of unidirectional sets of signals providing the received data signal and the received clock signal from the second integrated circuit to the first integrated circuit.

10. A method comprising:
generating a sample clock signal on a first integrated circuit based at least in part on a phase difference between a received clock signal received from a second integrated circuit and a received data signal received from the second integrated circuit separately from the received clock signal.

11. The method, as recited in claim 10, wherein the sample clock signal is based at least in part on a target sampling point of the received data signal.

12. The method, as recited in claim 10, wherein the generating the sample clock comprises:
generating an indicator of a phase difference between the received clock signal and the received data signal.

13. The method, as recited in claim 12, wherein the generating the sample clock further comprises:
generating at least one phase select signal and at least one interpolation control signal based at least in part on the indicator of the phase difference between the received clock signal and the received data signal.

14. The method, as recited in claim 13, wherein the generating the sample clock further comprises:
providing a plurality of phase clock signals having respective phases spaced equally across at least a predetermined portion of the period of the received clock signal;
selecting from the plurality of phase clock signals, a first phase clock signal having a first phase and a second phase clock signal having a second phase different from the first phase, the selecting being based on the phase select signal; and
generating an interpolated clock signal based on the first phase clock signal and the second phase clock signal in response to the interpolation control signal.

15. The method, as recited in claim 14, wherein the generating the sample clock further comprises:
phase-shifting the interpolated clock signal by a fraction of the period of the received clock signal to generate a phase-shifted version of the interpolated clock signal; and
generating the sample clock signal based on the interpolated clock signal and the phase-shifted version of the interpolated clock signal.

16. The method, as recited in claim 10, wherein the first and second integrated circuits are included on a printed circuit board and the first integrated circuit is coupled to the second integrated circuit by a communications link including a plurality of unidirectional sets of signals, at least one of the plurality of unidirectional sets of signals providing the received data signal and the received clock signal from the second integrated circuit to the first integrated circuit.

17. An apparatus comprising:
means for separately receiving on a first integrated circuit at least one received data signal and a received clock signal from a second integrated circuit; and
means for generating a sample clock signal on the first integrated circuit based at least in part on a phase difference between the received clock signal and the received data signal.

18. The apparatus, as recited in claim 17, wherein the means for generating the sample clock comprises:
means for generating a plurality of phase clock signals having respective phases spaced equally across at least a predetermined fraction of the period of the received clock signal.

19. The apparatus, as recited in claim 17, wherein the means for generating the sample clock comprises:
means for generating an interpolated clock signal based on at least one of the plurality of phase clock signals.
